(19) United States
(12) Patent Application Publication
(10) Pub. No.: US 2021/0013354 A1
(43) Pub. Date: Jan. 14, 2021

(54) SOLAR CELL

(71) Applicant: Tianjin Sanan Optoelectronics Co., Ltd., Tianjin (CN)

(72) Inventors: Guanzhou LIU, Tianjin (CN); Mingyang LI, Tianjin (CN); Senlin LI, Tianjin (CN); Minghui SONG, Tianjin (CN); Jingfeng BI, Tianjin (CN); Wenjun CHEN, Tianjin (CN)

(21) Appl. No.: 17/036,857

(22) Filed: Sep. 29, 2020

Related U.S. Application Data
(63) Continuation-in-part of application No. PCT/CN2018/087368, filed on May 17, 2018.

(51) Int. Cl. H01L 31/054; H01L 31/0725

(52) U.S. Cl. CPC H01L 31/0543; H01L 31/0725

(57) ABSTRACT

A solar cell includes a cell chip unit, and an optical unit. The optical unit includes a first optical layer, a second optical layer and a third optical layer that are sequentially disposed on the cell chip unit in such order. Each of the first optical layer and the third optical layer has a refractive index greater than that of the second optical layer.

### CROSS-REFERENCE TO RELATED APPLICATION

This application is a bypass continuation-in-part application of PCT International Application No. PCT/CN2018/087368 filed on May 17, 2018. The entire content of the International patent application is incorporated herein by reference.

### FIELD

The disclosure relates to a semiconductor optoelectronic device, and more particularly to a solar cell.

### BACKGROUND

GaInP/GaAs/Ge triple-junction solar cell has approached a limit in efficient space utilization. In order to further enhance the efficiency of the solar cell and achieve a better absorption efficiency under air mass zero (AMO) solar spectrum (i.e., the spectrum found at Earth's orbit around the sun or outside of Earth's atmosphere), there has been interest in developing a novel space solar cell with more junctions (e.g., four to six junctions). For a multijunction solar cell exhibiting enhanced light absorption in a broad light spectrum, an anti-reflection film can be provided to reduce the reflection of a light having a broad range of wavelengths. In a conventional triple-junction solar cell, various double-layered anti-reflection films have been used for controlling the light reflection. Among them, a TiO₂/Al₂O₃ layered structure which includes a TiO₂ layer having a thickness ranging from 40 nm to 55 nm, and a Al₂O₃ layer having a thickness ranging from 60 nm to 80 nm is the most widely used one. However, such double-layered anti-reflection film is no longer sufficient to meet the requirement for reducing the light reflection in a broad light spectrum. Therefore, there is a need to design an anti-reflection film having a multi-layered structure (i.e., more than two layers).

A triple-layered anti-reflection film is generally designed to have a graded refractive index structure. For example, Chinese Invention Patent Application No. 201210535447.X discloses a photovoltaic cell including an anti-reflection coating that has a triple-layered composite structure made of silicon nitride and a method for making the same. Three silicon nitride layers to form such composite structure are sequentially coated on a surface of a silicon chip of the photovoltaic cell, and have refractive indices gradually decreasing in a direction away from the surface of the silicon chip. Such composite structure is conducive for broadening a light absorption bandwidth of the silicon chip in each frequency band. However, subjecting a same material to a fabrication process to make the composite structure having three layers with different refractive indices is complicated and difficult to control. If such composite structure is to be made from different materials having different refractive indices for each layer, selection of proper materials would be difficult and the requirement of the facility for making such composite structure (e.g., electron beam evaporator) would be challenging.

Another conventional anti-reflection film having the graded refractive index structure is a HL structure optical film that includes multiple HL pairs of optical layers, each pair containing a high refractive index optical layer and a low refractive index optical layer, and the high refractive index optical layers and the low refractive index optical layers in the optical film are alternately stacked. Theoretically, each HL pair has a refractive index between those of the low refractive index optical layer and the high refractive index optical layer. An effective refractive index of each HL pair in such optical film can be independently controlled by adjusting a ratio of the thickness of the high and low refractive index optical layers to the low refractive index optical layer, such that different HL pairs may have different refractive indices, thereby obtaining the anti-reflection film with a gradient of refractive index. In Chinese Invention Patent Application No. 201210539205.8, HL pairs of optical layers are used to make a wide spectral anti-reflection film for multijunction solar cell. However, at least four optical layers (i.e., two HL pairs) are required to exhibit a gradient of refractive index, and the thickness of each optical layer is required to be precisely controlled, resulting in a complicated fabrication process.

In addition, it should be taken into consideration that a packaging material (e.g., silica gel, glass, etc.), which is subsequently disposed on the anti-reflection film and the chip, may also affect the anti-reflective property to be achieved. For example, the packaging material used in the solar cell may include a silica gel and a layer of radiation-shielding glass that is adhered to the anti-reflection film and the chip through the silica gel. Since each of the silica gel and the radiation-shielding glass has a refractive index ranging from 1.45 to 1.55, a magnesium fluoride (MgF₂) film is needed to be further deposited on the layer of radiation-shielding glass for reducing light reflected therefrom.

### SUMMARY

Therefore, an object of the disclosure is to provide a solar cell that can alleviate or eliminate at least one of the drawbacks of the prior art.

According to the disclosure, the solar cell includes a cell chip unit and an optical unit. The optical unit includes a first optical layer, a second optical layer and a third optical layer that are sequentially disposed on the cell chip unit in such order. Each of the first optical layer and the third optical layer has a refractive index greater than that of the second optical layer.

### BRIEF DESCRIPTION OF THE DRAWINGS

Other features and advantages of the disclosure will become apparent in the following detailed description of the embodiments with reference to the accompanying drawings, of which:

FIG. 1 is a schematic view illustrating an embodiment of a solar cell according to the disclosure;

FIG. 2 is a plot showing simulated spectral reflectance curves of anti-reflection structures of Example and Comparative Example on a GaInP/AlInP layered structure;

FIG. 3 is a plot showing spectral reflectance curves of the anti-reflection structures of Example and Comparative Example on a GaInP/GaAs/InGaAs triple-junction solar cell; and

FIG. 4 is a plot showing the external quantum efficiency of the GaInP/GaAs/InGaAs triple-junction solar cells with or without a respective one of the anti-reflection structures of Example and Comparative Example.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

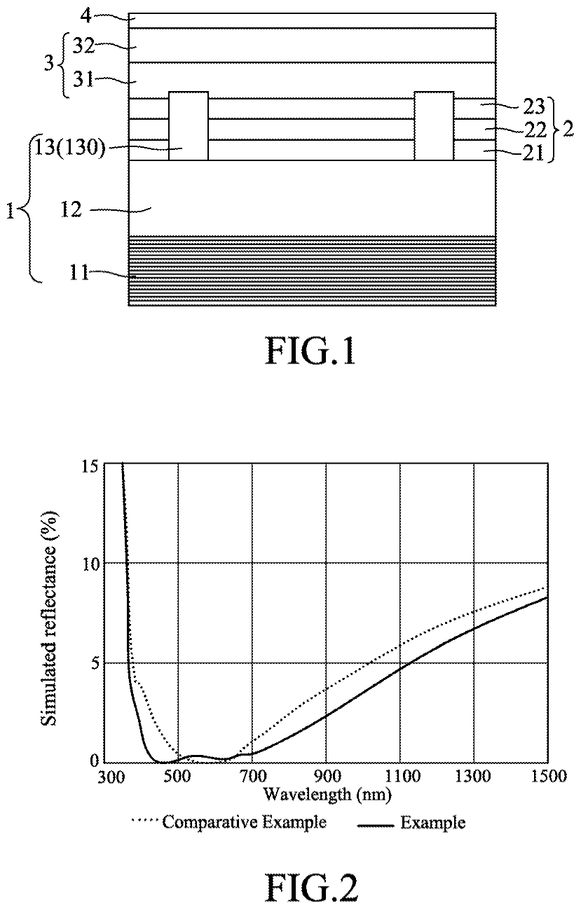

Referring to FIG. 1, an embodiment of a solar cell according to the present disclosure includes a cell chip unit 1, an optical unit 2, and a packaging layer 3.

The cell chip unit 1 includes a substrate 11 and a semiconductor structure 12 disposed on the substrate 11. There are no particular limitations on the material for making the substrate 11. In this embodiment, the substrate 11 is made of silicon (Si). The semiconductor structure 12 includes at least one p-n junction. The semiconductor structure 12 may include at least one chemical element selected from the group consisting of Si, Ge, C, Ga, In, P, As, Cu, Se, Ca, Ti, and chemical compounds thereof. In this embodiment, the semiconductor structure 12 is a GaInP/GaAs/InGaAs triple-junction structure that is initially formed on a GaAs temporary substrate in an up-side-down manner by a metal organic chemical vapor deposition (MOCVD), and that is then transferred from the GaAs temporary substrate to the substrate 11 through a metal bonding method.

The cell chip unit 1 further includes an electrode unit 13 which is formed on the semiconductor structure 12 by, e.g., photolithography and a metal evaporation process. Examples of a material for making the electrode unit 13 may include, but are not limited to, Au, Ge, Ni, Ti, Ag, and combinations thereof. The electrode unit 13 may include a front electrode 130 and a back electrode (not shown in the figure) that are respectively disposed on two opposite sides of the semiconductor structure 12, and that are respectively electrically connected to a p-type region and a n-type region of the p-n junction of the semiconductor structure 12. In this embodiment, the front electrode 130 of the electrode unit 13 has a AuGeNi/Au/Ti/Ag/Au structure.

The optical unit 2 includes a triple-layered structure, i.e., a first optical layer 21, a second optical layer 22 and a third optical layer 23 that are sequentially disposed on the cell chip unit 1 in such order through, e.g., an evaporation process. The optical unit 2 is configured to be transmissive to a light having a wavelength with a relative broader range, e.g., from 350 nm to 1800 nm. Each of the first optical layer 21 and the third optical layer 23 has a refractive index greater than that of the second optical layer 22.

The refractive index of the first optical layer 21 may range from 1.8 to 2.6. The first optical layer 21 may have a thickness that ranges from 30 nm to 60 nm. The first optical layer 21 may be made of an inorganic insulating material, such as an oxide, a nitride, a halide, a sulfide, or combinations thereof. Examples of the inorganic insulating material for making the first optical layer 21 may include, but are not limited to an oxide, a nitride or a sulfide, such as titanium oxide (TiO₂), zinc sulphide (ZnS), silicon nitride (Si₃N₄), tantalum pentoxide (Ta₂O₅), hafnium oxide (HfO₂), zirconia (ZrO₂), indium oxide (InO), lanthanum oxide (La₂O₃), zinc oxide (ZnO), and combinations thereof.

The refractive index of the second optical layer 22 may range from 1.3 to 1.8. The second optical layer 22 may have a thickness that ranges from 30 nm to 70 nm. The second optical layer 22 may be made of an inorganic insulating material, such as an oxide, a nitride, a halide, a sulfide, or combinations thereof. Examples of the inorganic insulating material for making the second optical layer 22 may include, but are not limited to silicon oxide (SiO₂), aluminium oxide (Al₂O₃), aluminium oxynitride, magnesiumoxide (MgO), magnesium fluoride (MgF₂), barium fluoride (BaF₂), lithium fluoride (LiF), lanthanum fluoride (LaF₃), aluminium fluoride (AlF₃), and combinations thereof.

The refractive index of the third optical layer 23 may range from 1.8 to 2.6. The third optical layer 23 may have a thickness that ranges from 5 nm to 15 nm. The third optical layer 23 may be made of an inorganic insulating material, such as an oxide, a nitride, a halide, a sulfide, or combinations thereof. Examples of the inorganic insulating material for making the third optical layer 23 may include, but are not limited to, titanium oxide (TiO₂), zinc sulphide (ZnS), silicon nitride (Si₃N₄), tantalum pentoxide (Ta₂O₅), hafnium oxide (HfO₂), zirconia (ZrO₂), indium oxide (InO), lanthanum oxide (La₂O₃), zinc oxide (ZnO), and combinations thereof.

In this embodiment, the first optical layer 21 is made of TiO₂, and has a thickness of 42 nm and a refractive index of 2.4. The second optical layer 22 is made of Al₂O₃ thin film, and has a thickness of 49 nm and a refractive index of 1.6. The third optical layer 23 is made of TiO₂, and has a thickness of 7 nm and a refractive index of 2.4. It should be noted that although the first and third optical layers 21, 23 are made of the same material in this embodiment, the first optical layer 21 and the third optical layer 23 may be made of different materials. For example, in a variation of the embodiment, the third optical layer 23 is made of Si₃N₄ or Ta₂O₅ instead of TiO₂.

The packaging layer 3 is disposed on the optical unit 2 opposite to the cell chip unit 1. The packaging layer 3 may have a refractive index lower than that of the third optical layer 23. In certain embodiments, the refractive index of the packaging layer 3 ranges from 1.45 to 1.55. The packaging layer 3 may include at least one material, for example, but is not limited to, polyimide, polyolefin elastomer, ethylene vinyl acetate, silica gel, glass, resin, and combinations thereof.

In this embodiment, the packaging layer 3 includes a silica gel 31 and a radiation-shielding glass 32 that are sequentially disposed on the optical unit 2 in such order. The silica gel 31 has a refractive index of 1.5, and is formed by a curing process at 100° C.

The solar cell may further include a magnesium fluoride layer 4 which is formed on the radiation-shielding glass 32 opposite to the optical unit 2 in advance by an electron beam evaporation process, so as to lower the reflectance of the radiation-shielding glass 32. The magnesium fluoride layer 4 may have a thickness of 80 nm.

The disclosure will be further described by way of the following examples. However, it should be understood that the following examples are solely intended for the purpose of illustration and should not be construed as limiting the disclosure in practice.

### Examples

To determine the anti-reflection effect of the optical unit 2 according to this disclosure, an anti-reflection structure of Example (E) is prepared and includes the optical unit 2 (i.e., the triple-layered structure), and the packaging layer 3 (i.e., the silica gel 31 and the radiation-shielding glass 32 that are sequentially disposed on the optical unit 2 in such order). The optical unit 2 includes the first optical layer 21 made of TiO₂ (42 nm), the second optical layer 22 made of Al₂O₃ (49 nm), and the third optical layer 23 made of TiO₂ (7 nm).

For comparison purpose, an anti-reflection structure of Comparative Example (CE), which includes a double-layered structure (i.e., a TiO₂ layer (42 nm) and a Al₂O₃ layer (72 nm)), and the silica gel and the radiation-shielding glass that are sequentially disposed on the double-layered structure in such order, is prepared.

The anti-reflection structures of Example and Comparative Example are first subjected to a simulated analysis of spectral reflectance on a GaInP/AlInP layered structure (instead of a triple-junction solar cell), which includes a GaInP layer (1 μm) and an AlInP layer (25 nm). The GaInP/AlInP layered structure is chosen for the following reasons.

Specifically, in the triple-junction solar cell such as GaInP (i.e., a top subcell)/GaAs (i.e., a middle subcell)/InGaAs (i.e., a bottom subcell), the top subcell includes a top AlInP window layer having a refractive index which ranges from 2.8 to 3.2, and which is higher than a refractive index of the third optical layer 23 made of TiO₂ (i.e., 2.4) and lower than a refractive index of each of the remaining layers of the top subcell, and all layers of the middle and bottom subcells (having refractive indices ranging from 3.2 to 4.5). That is, the top AlInP window layer may exert a certain anti-reflective effect. As such, simulation of the spectral reflectance on the GaInP/AlInP layered structure can effectively reflect the anti-reflective effect of the anti-reflection structure on the triple-junction solar cell, without complicating the simulation process due to the number of layers of the semiconductor structure inside the solar cell.

Referring to FIG. 2, as compared with Comparative Example, the anti-reflection structure of Example has a better anti-reflection effect for a light having a wavelength that ranges from 400 nm to 500 nm and from 700 nm to 1500 nm.

Thereafter, the anti-reflection structures of Example and Comparative Example are further subjected to determination of the spectral reflectance on the GaInP/GaAs/InGaAs triple-junction solar cell.

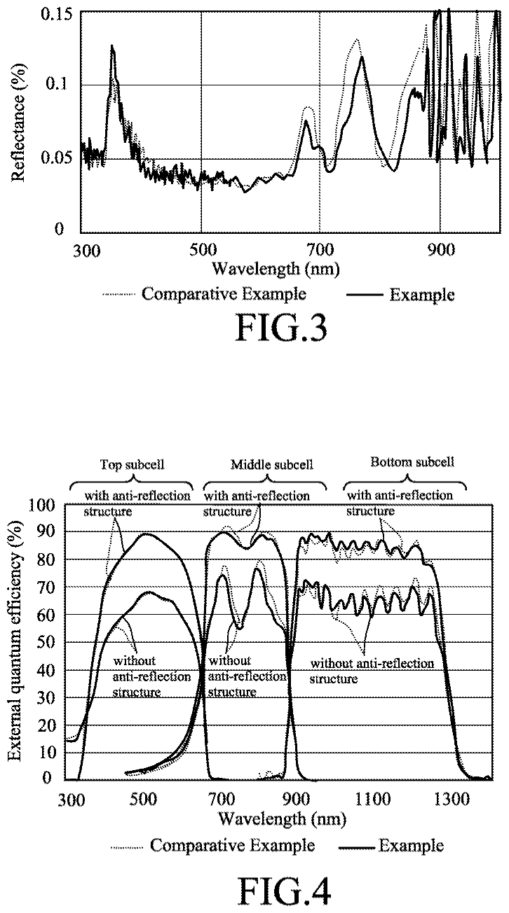

As shown in FIG. 3, it can be seen that as compared with Comparative Example, the anti-reflection structure of Example has an improved anti-reflection effect for a light having a wavelength that ranges from 400 nm to 450 nm and from 700 nm to 1000 nm. The result is similar to the simulation result shown in FIG. 2.

The two GaInP/GaAs/InGaAs triple-junction solar cells respectively having the anti-reflection structures of Example and Comparative Example are also subjected to determination of an external quantum efficiency. In comparison, a GaInP/GaAs/InGaAs triple-junction solar cell without any anti-reflection structure is subjected to the same analysis. The results are shown in FIG. 4. It should be noted that the external quantum efficiency of the top (T) subcell is measured in a wavelength range of 300 nm to 750 nm, the external quantum efficiency of the middle (M) subcell is measured in a wavelength range of 450 nm to 750 nm, and the external quantum efficiency of the bottom (B) subcell is measured in a wavelength range of 800 nm to 1400 nm.

By analyzing the result of the external quantum efficiency shown in FIG. 4 in combination with AMO solar spectrum, the photocurrent density of each of the top (T), middle (M) and bottom (B) subcells in the GaInP/GaAs/InGaAs triple junction solar cell can be calculated (see Table 1). In addition, an increasing ratio of photocurrent density can be obtained by comparing the results of the GaInP/GaAs/InGaAs triple junction solar cells with and without the anti-reflection structure based on the following equation:

A=[(B−C)/C]×100%

wherein:
A=increasing ratio of photocurrent density
B=the photocurrent density of a respective one of the subcells in the solar cell with the anti-reflection structure
C=the photocurrent density of the respective one of the subcells in the solar cell without the anti-reflection structure.

TABLE 1

| | Solar cell without | | | Solar cell with | | | | | |
|---|---|---|---|---|---|---|---|---|---|
| | anti-reflection structure | | | anti-reflection structure | | | Increasing ratio of | | |
| | Photocurrent density of subcells (mA/cm²) | | | | | | photocurrent density (%) | | |
| | T | M | B | T | M | B | T | M | B |
| E | 12.584 | 12.355 | 14.758 | 16.621 | 16.313 | 18.965 | 32.08 | 32.03 | 28.51 |
| CE | 12.578 | 12.567 | 14.987 | 16.601 | 16.437 | 18.754 | 31.98 | 30.79 | 25.14 |

As shown in Table 1, for the solar cell with the anti-reflection structure of Example, the increasing ratio of photocurrent density of the top subcell (GaInP) is close to that of the solar cell with the anti-reflection structure of Comparative Example. In addition, the increasing ratios of photo current density of the middle subcell (GaAs) and the bottom subcell (InGaAs) in the solar cell with anti-reflection structure of Example are significantly greater than those obtained in the solar cell with anti-reflection structure of Comparative Example.

The above results indicate that as compared with the conventional anti-reflection double-layered structure, the optical unit 2 (triple-layered structure) of this disclosure exhibits an improved anti-reflection effect. In addition, the optical unit 2 can be made by simply modifying the procedures for making the conventional anti-reflection double-layered structure, and thus can be adapted for mass production.

In summary, by virtue of the second optical layer 22 having the refractive index lower than that of each of the first optical layer 21 and the third optical layer 23, the optical unit 2 can effectively cooperate with the packaging layer 3 to achieve an improved anti-reflection effect, thereby improving the properties of the solar cell of this disclosure.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A solar cell, comprising:
a cell chip unit; and
an optical unit which includes a first optical layer, a second optical layer and a third optical layer that are sequentially disposed on said cell chip unit in such order, each of said first optical layer and said third optical layer having a refractive index greater than that of said second optical layer.

2. The solar cell of claim 1, wherein said cell chip unit includes a semiconductor structure which includes at least one p-n junction, and an electrode unit which is formed on said semiconductor structure.

3. The solar cell of claim 2, wherein said semiconductor structure includes at least one chemical element selected from the group consisting of Si, Ge, C, Ga, In, P, As, Cu, Se, Ca, Ti, and chemical compounds thereof.

4. The solar cell of claim 1, wherein the refractive index of each of said first optical layer and said third optical layer independently ranges from 1.8 to 2.6.

5. The solar cell of claim 1, wherein the refractive index of said second optical layer ranges from 1.3 to 1.8.

6. The solar cell of claim 1, further comprising a packaging layer which is disposed on said optical unit opposite to said cell chip unit.

7. The solar cell of claim 6, wherein said packaging layer has a refractive index that ranges from 1.45 to 1.55.

8. The solar cell of claim 6, wherein said packaging layer has a refractive index lower than that of said third optical layer.

9. The solar cell of claim 1, wherein said optical unit is configured to be transmissive to a light having a wavelength that ranges from 350 nm to 1800 nm.

10. The solar cell of claim 1, wherein each of said first optical layer, said second optical layer and said third optical layer is made of an inorganic insulating material.

11. The solar cell of claim 10, wherein said inorganic insulating material is selected from the group consisting of an oxide, a nitride, a sulfide, a halide, and combinations thereof.

12. The solar cell of claim 11, wherein said inorganic insulating material for making each of said first optical layer and said third optical layer is selected from the group consisting of titanium oxide (TiO₂), zinc sulphide (ZnS), silicon nitride (Si₃N₄), tantalum pentoxide (Ta₂O₅), hafnium oxide (HfO₂), zirconia (ZrO₂), indium oxide (InO), lanthanum oxide (La₂O₃), zinc oxide (ZnO), and combinations thereof.

13. The solar cell of claim 11, wherein said inorganic insulating material for making said second optical layer is selected from the group consisting of silicon oxide (SiO₂), aluminium oxide (Al₂O₃), aluminium oxynitride, magnesium oxide (MgO), magnesium fluoride (MgF₂), barium fluoride (BaF₂), lithium fluoride (LiF), lanthanum fluoride (LaF₃), aluminium fluoride (AlF₃), and combinations thereof.

14. The solar cell of claim 1, wherein said first optical layer is made of the same material as that of said third optical layer.

15. The solar cell of claim 6, wherein said packaging layer includes at least one material selected from the group consisting of polyimide, polyolefin elastomer, ethylene vinyl acetate, silica gel, glass, and resin.

16. The solar cell of claim 6, wherein said packaging layer includes a silica gel and a radiation-shielding glass that are sequentially disposed on said optical unit in such order.

17. The solar cell of claim 1, further including a magnesium fluoride layer that is disposed on said packaging layer opposite to said optical unit.

18. The solar cell of claim 1, wherein said first optical layer has a thickness that ranges from 30 nm to 60 nm.

19. The solar cell of claim 1, wherein said second optical layer has a thickness that ranges from 30 nm to 70 nm.

20. The solar cell of claim 1, wherein said third optical layer has a thickness that ranges from 5 nm to 15 nm.
